(19) United States
(12) Patent Application Publication
(10) Pub. No.: US 2015/0014641 A1
(43) Pub. Date: Jan. 15, 2015

(54) ORGANIC LIGHT EMITTING DIODE DISPLAY

(71) Applicant: Samsung Display Co., Ltd., Yongin-city (KR)

(72) Inventors: Jin-Goo JUNG, Yongin-city (KR); Chung Yl, Yongin-city (KR)

(73) Assignee: Samsung Display Co., Ltd., Yongin-city (KR)

(21) Appl. No.: 14/107,578

(22) Filed: Dec. 16, 2013

(30) Foreign Application Priority Data
Jul. 12, 2013 (KR) 10-2013-0082148

(51) Int. Cl. H01L 27/32; H01L 29/66

(52) U.S. Cl. CPC H01L 27/3262; H01L 27/3265; H01L 29/66742
USPC 257/40; 438/158

(57) ABSTRACT

An organic light emitting diode (OLED) display according to the present invention includes a substrate; a driving gate electrode formed on the substrate; and a first gate insulating layer covering the substrate and the driving gate electrode. A semiconductor layer formed on the first gate insulating layer and including a switching semiconductor layer and a driving semiconductor layer separated from each other. A second gate insulating layer disposed covering the semiconductor layer. A switching gate electrode formed on the second gate insulating layer and overlapping the switching semiconductor layer. An interlayer insulating layer is disposed covering the switching gate electrode and the second gate insulating layer, wherein a thickness of the first gate insulating layer is thicker a thickness of the second gate insulating layer.

### CROSS-REFERENCE TO RELATED APPLICATION

This application claims priority to and the benefit of Korean Patent Application No. 10-2013-0082148 filed on Jul. 12, 2013, which is hereby incorporated by reference for all purposes as if fully set forth herein.

### BACKGROUND OF THE INVENTION

1. Field

Exemplary embodiments of the present invention relate to an organic light emitting diode (OLED) display.

2. Description of the Background

An organic light emitting diode display may include two electrodes and an organic light emitting layer positioned therebetween. Electrons injected from a cathode that is an electrode and holes injected from an anode that is another electrode are bonded to each other in the organic light emitting layer to form excitons. Light is emitted while the excitons discharge energy.

The organic light emitting diode display may include a plurality of pixels. The organic light emitting diode, for example, is formed of a cathode, an anode, and an organic light emitting layer. A plurality of thin film transistors and capacitors for driving the organic light emitting diode may be formed in each pixel. The plurality of thin film transistors may include a switching thin film transistor and a driving thin film transistor.

When light emitted from the organic light emitting diode is displayed to have a range from a black color to a white color according to a driving current Id flowing through the organic light emitting diode, a difference between a gate voltage displaying the black color and a gate voltage displaying the white color is defined as a driving range of the gate voltage. The higher the resolution of the organic light emitting diode display is, the smaller the size of each pixel is, and thus an amount of flowing current per pixel is reduced such that a driving range of a gate voltage applied to a gate electrode of the switching transistor and the driving transistor becomes narrow. Accordingly, it is difficult to adjust the magnitude of the gate voltage Vgs applied to the driving transistor so as to ensure a large grayscale range.

The above information disclosed in this Background section is only to set up Applicant's recognition of problems within existing art and merely for enhancement of understanding of the background of the invention based on the identified source of problems, and therefore the above information cannot be used as prior art in determining obviousness into the present invention.

### SUMMARY

Exemplary embodiments of the present invention provide an organic light emitting diode display broadening a driving range of a gate voltage applied to a driving transistor to display many grayscales and improving storage capacitance.

Additional features of the invention will be set forth in the description which follows, and in part will be apparent from the description, or may be learned by practice of the invention.

Still other aspects, features, and advantages of the present invention are readily apparent from the following detailed description, simply by illustrating a number of particular embodiments and implementations, including the best mode contemplated for carrying out the present invention. The present invention is also capable of other and different embodiments, and its several details can be modified in various obvious respects, all without departing from the spirit and scope of the present invention. Accordingly, the drawing and description are to be regarded as illustrative in nature, and not as restrictive.

Exemplary embodiments of the present invention disclose an organic light emitting diode. The diode includes a substrate and a driving gate electrode disposed on the substrate. The diode includes a first gate insulating layer covering the substrate and the driving gate electrode. The diode includes a semiconductor layer that is disposed on the first gate insulating layer and including a switching semiconductor layer and a driving semiconductor layer spaced apart from each other. The diode includes a second gate insulating layer covering the semiconductor layer. The diode includes a switching gate electrode disposed on the second gate insulating layer and overlapping the switching semiconductor layer. The diode includes an interlayer insulating layer disposed covering the switching gate electrode and the second gate insulating layer. A thickness of the first gate insulating layer is greater than a thickness of the second gate insulating layer.

Exemplary embodiments of the present invention disclose a display. The display includes a driving gate electrode disposed on a substrate. The display includes a first gate insulating layer disposed on the driving gate electrode. The display includes a driving semiconductor layer, a switching semiconductor layer, and a light emission control semiconductor layer disposed on the first gate insulating layer, the driving gate electrode being disposed under the driving semiconductor layer. A thickness of the first gate insulating layer is greater than a thickness of the second gate insulating layer. An interval between the driving semiconductor layer and the driving gate electrode is widened.

Exemplary embodiments of the present invention disclose a method. The method includes forming a driving gate electrode on a substrate. The method includes forming a first gate insulator covering the substrate and the driving gate electrode. The method includes forming a semiconductor layer on the first gate insulating layer, the semiconductor layer comprising a switching semiconductor layer and a driving semiconductor layer spaced apart from each other, and a second gate insulating layer covering the semiconductor layer. The method includes forming a switching gate electrode on the second gate insulating layer, the switching gate electrode overlapping the switching semiconductor layer. The method includes forming an interlayer insulating layer covering the switching gate electrode and the second gate insulating layer, wherein the first gate insulating layer is formed thicker than the second gate insulating layer.

It is to be understood that both the foregoing general description and the following detailed description are exemplary and explanatory and are intended to provide further explanation of the invention as claimed.

### BRIEF DESCRIPTION OF THE DRAWINGS

FIG. 1 is a circuit view of one pixel of an organic light emitting diode display according to exemplary embodiments of the present invention.

FIG. 2 is a view schematically illustrating a plurality of transistors and capacitors of the organic light emitting diode display according to exemplary embodiments of the present invention.

FIG. 3 is a layout view of one pixel of FIG. 2.

FIG. 4 is a cross-sectional view of the organic light emitting diode display of FIG. 3, which is taken along line IV-IV.

FIG. 5 is a cross-sectional view of the organic light emitting diode display of FIG. 3, which is taken along line V-V′ and line V′-V″.

FIG. 6 is a layout view of one pixel of an organic light emitting diode display according to exemplary embodiments of the present invention.

FIG. 7 is a cross-sectional view of the organic light emitting diode display of FIG. 6, which is taken along line VII-VII.

FIG. 8 is a cross-sectional view of the organic light emitting diode display of FIG. 6 taken along line VIII-VIII′ and VIII′-VIII″.

FIG. 9 is a view schematically illustrating a plurality of transistors and capacitors of the organic light emitting diode display according to the third exemplary embodiment of the present invention.

FIG. 10 is a layout view of one pixel of FIG. 9.

FIG. 11 is a cross-sectional view of the organic light emitting diode (OLED) display of FIG. 10 taken along the line XI-XI.

FIG. 12 is a cross-sectional view of the organic light emitting diode (OLED) display of FIG. 10 taken along the line XII-XII′ and XII′-XII″.

FIG. 13 is a layout view of one pixel of an organic light emitting diode display according to exemplary embodiments of the present invention.

### DETAILED DESCRIPTION OF THE ILLUSTRATED EMBODIMENTS

An organic light emitting diode (OLED) display and a method for making an organic light emitting diode are disclosed. In the following description, for the purposes of explanation, numerous specific details are set forth in order to provide a thorough understanding of the present invention. It is apparent, however, to one skilled in the art that the present invention may be practiced without these specific details or with an equivalent arrangement. In other instances, well-known structures and devices are shown in block diagram form in order to avoid unnecessarily obscuring the present invention.

The drawings and description are to be regarded as illustrative in nature and not restrictive. Like reference numerals designate like elements throughout the specification.

Further, the size and thickness of each component shown in the drawings are arbitrarily shown for understanding and ease of description, but the present invention is not limited thereto.

In the drawings, the thickness of layers, films, panels, and regions are exaggerated for clarity. In the drawings, for better understanding and ease of description, the thickness of some layers and areas is exaggerated. It will be understood that when an element such as a layer, film, region, or substrate is referred to as being “on” another element, it can be directly on the other element or intervening elements may also be present.

In addition, unless explicitly described to the contrary, the word “comprise” and variations such as “comprises” or “comprising” will be understood to imply the inclusion of stated elements but not the exclusion of any other elements. In addition, in the specification, the word “on” means positioning on or below the object portion, but does not essentially mean positioning on the upper side of the object portion based on a gravity direction.

Further, in the specification, the phrase “on a flat surface” means when an object portion is viewed from above, and the phrase “on a cross-section” means when a cross-section taken by vertically cutting an object portion is viewed from the side.

It will be understood that for the purposes of this disclosure, “at least one of X, Y, and Z” can be construed as X only, Y only, Z only, or any combination of two or more items X, Y, and Z (e.g., XYZ, XYY, YZ, ZZ).

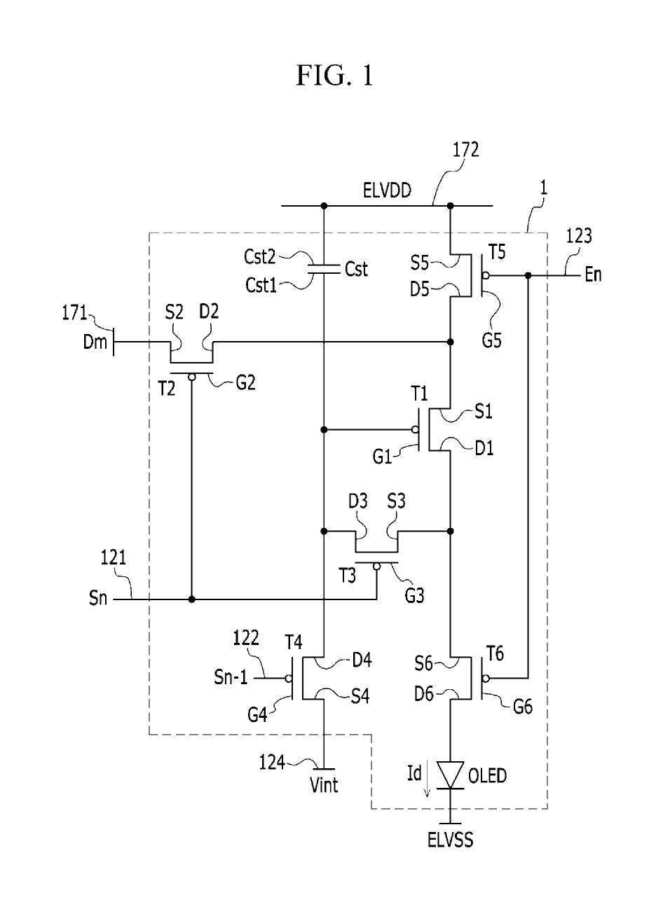

Now, an organic light emitting diode display according to exemplary embodiments of the present invention will be described in detail with reference to FIGS. 1 to 5.

FIG. 1 is a circuit view of one pixel of an organic light emitting diode display according to exemplary embodiments of the present invention.

As illustrated in FIG. 1, one pixel 1 of the organic light emitting diode display may include a plurality of signal lines 121, 122, 123, 124, 171, and 172, and a plurality of transistors T1, T2, T3, T4, T5, and T6, a storage capacitor Cst, and an organic light emitting diode (OLED) connected to the plurality of signal lines.

For example, the transistors may include a driving transistor (driving thin film transistor) T1, a switching transistor (switching thin film transistor) T2, a compensation transistor T3, an initialization transistor T4, an operation control transistor T5, and a light emission control transistor T6.

The signal lines may include a scan line 121 transferring a scan signal Sn, a prior scan line 122 transferring a prior scan signal Sn-1 to the initialization transistor T4, a light emission control line 123 transferring a light emission control signal En to the operation control transistor T5 and the light emission control transistor T6, a data line 171 crossing the scan line 121 and transferring a data signal Dm, a driving voltage line 172 transferring a driving voltage ELVDD and formed almost parallel to the data line 171, and an initialization voltage line 124 transferring an initialization voltage Vint initializing the driving transistor T1.

According to exemplary embodiments, a gate electrode G1 of the driving transistor T1 is connected to an end Cst1 of the storage capacitor Cst, a source electrode S1 of the driving transistor T1 is connected via the operation control transistor T5 to the driving voltage line 172, and the drain electrode D1 of the driving transistor T1 is electrically connected via the light emission control transistor T6 to an anode of the organic light emitting diode (OLED). The driving transistor T1 receives the data signal Dm according to a switching operation of the switching transistor T2 to supply a driving current Id to the organic light emitting diode (OLED).

For example, a gate electrode G2 of the switching transistor T2 is connected to the scan line 121, a source electrode S2 of the switching transistor T2 is connected to the data line 171, and a drain electrode D2 of the switching transistor T2 is connected via the operation control transistor T5 to the driving voltage line 172 while being connected to the source electrode S1 of the driving transistor T1. The switching transistor T2 is turned on according to the scan signal Sn transferred through the scan line 121 to perform a switching operation for transferring the data signal Dm transferred to the data line 171 to the source electrode of the driving transistor T1.

For example, a gate electrode G3 of the compensation transistor T3 is connected to the scan line 121, a source electrode S3 of the compensation transistor T3 is connected via the light emission control transistor T6 to the anode of the organic light emitting diode (OLED) while being connected to the drain electrode D1 of the driving transistor T1, and a drain electrode D3 of the compensation transistor T3 is connected to an end Cst1 of the storage capacitor Cst, a drain electrode D4 of the initialization transistor T4, and the gate electrode G1 of the driving transistor T1 together. The compensation transistor T3 is turned on according to the scan signal Sn transferred through the scan line 121 to connect the gate electrode G1 and the drain electrode D1 of the driving transistor T1 to each other, thus performing diode-connection of the driving transistor T1.

For example, a gate electrode G4 of the initialization transistor T4 is connected to the prior scan line 122, the source electrode S4 of the initialization transistor T4 is connected to the initialization voltage line 124, and the drain electrode D4 of the initialization transistor T4 is connected to an end Cst1 of the storage capacitor Cst, the drain electrode D3 of the compensation transistor T3, and the gate electrode G1 of the driving transistor T1 together. The initialization transistor T4 is turned on according to the prior scan signal Sn-1 transferred through the prior scan line 122 to transfer the initialization voltage Vint to the gate electrode G1 of the driving transistor T1, thus performing an initialization operation of initializing the voltage of the gate electrode G1 of the driving transistor T1.

For example, a gate electrode G5 of the operation control transistor T5 is connected to the light emission control line 123, a source electrode S5 of the operation control transistor T5 is connected to the driving voltage line 172, and a drain electrode D5 of the operation control transistor T5 is connected to the source electrode S1 of the driving transistor T1 and the drain electrode S2 of the switching transistor T2.

A gate electrode G6 of the light emission control transistor T6 is connected to the light emission control line 123, a source electrode S6 of the light emission control transistor T6 is connected to the drain electrode D1 of the driving transistor T1 and the source electrode S3 of the compensation transistor T3, and a drain electrode D6 of the light emission control transistor T6 is electrically connected to the anode of the organic light emitting diode (OLED). The operation control transistor T5 and the light emission control transistor T6 are simultaneously turned on according to the light emission control signal En transferred through the light emission control line 123 to transfer the driving voltage ELVDD to the organic light emitting diode (OLED), thus allowing the driving current Id to flow in the organic light emitting diode (OLED).

Another end Cst2 of the storage capacitor Cst is connected to the driving voltage line 172, and a cathode of the organic light emitting diode (OLED) is connected to a common voltage ELVSS. Accordingly, the organic light emitting diode (OLED) receives the driving current Id from the driving transistor T1 to emit light, thereby displaying an image.

Hereinafter, an operation process of one pixel of the organic light emitting diode display according to exemplary embodiments of the present invention will be described in detail.

First, the prior scan signal Sn-1 at a low level is supplied through the prior scan line 122 during an initialization period. Then, the initialization transistor T4 is turned on corresponding to the prior scan signal Sn-1 at the low level, and the initialization voltage Vint is connected from the initialization voltage line 124 through the initialization transistor T4 to the gate electrode of the driving transistor T1 to initialize the driving transistor T1 by the initialization voltage Vint.

Subsequently, the scan signal Sn at the low level is supplied through the scan line 121 during a data programming period. Then, the switching transistor T2 and the compensation transistor T3 are turned on corresponding to the scan signal Sn at the low level.

In this case, the driving transistor T1 is diode-connected transistor by the turned on compensation transistor T3, and biased in a forward direction.

Then, a compensation voltage Dm+Vth (Vth is a negative value) obtained by subtracting a threshold voltage Vth of the driving transistor T1 from the data signal Dm supplied from the data line 171 is applied to the gate electrode of the driving transistor T1.

The driving voltage ELVDD and the compensation voltage Dm+Vth are applied to both ends of the storage capacitor Cst, and a charge corresponding to a voltage difference between both ends is stored in the storage capacitor Cst. Thereafter, the level of the light emission control signal En supplied from the light emission control line 123 during the light emission period is changed from the high level to the low level. Then, the operation control transistor T5 and the light emission control transistor T6 are turned on by the light emission control signal En at the low level during the light emission period.

Then, the driving current Id is generated according to a voltage difference between the gate electrode of the driving transistor T1 and the driving voltage ELVDD, and the driving current Id is supplied through the light emission control transistor T6 to the organic light emitting diode (OLED). A gate-source voltage Vgs of the driving transistor T1 is maintained at “(Dm+Vth)-ELVDD” by the storage capacitor Cst during the light emission period, and the driving current Id is proportional to a square of a value obtained by subtracting the threshold voltage from a source-gate voltage, that is, “(Dm-ELVDD),” according to a current-voltage relationship of the driving transistor T1. Accordingly, the driving current Id is determined regardless of the threshold voltage Vth of the driving transistor T1.

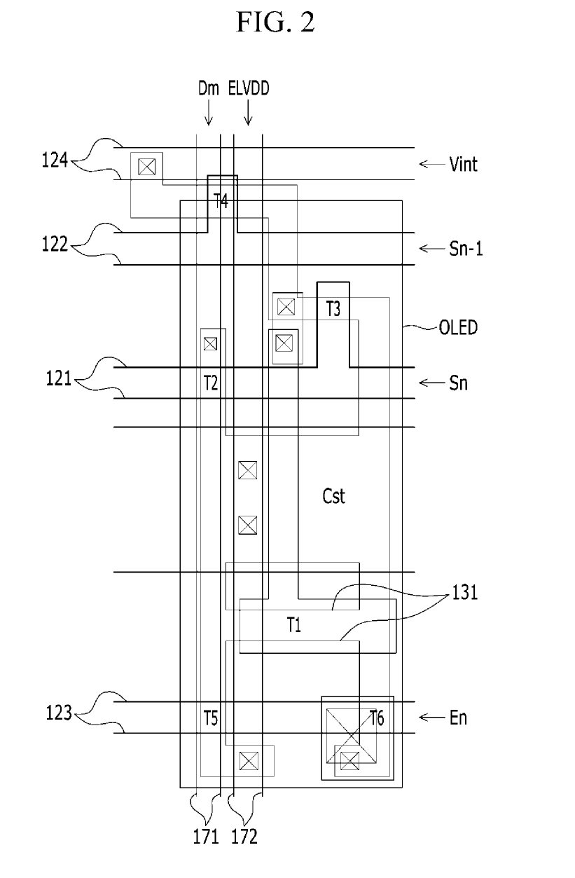

Now, a detailed structure of the pixel of the organic light emitting diode display illustrated in FIG. 1 will be described in detail with reference to FIGS. 2 to 5 together with FIG. 1.

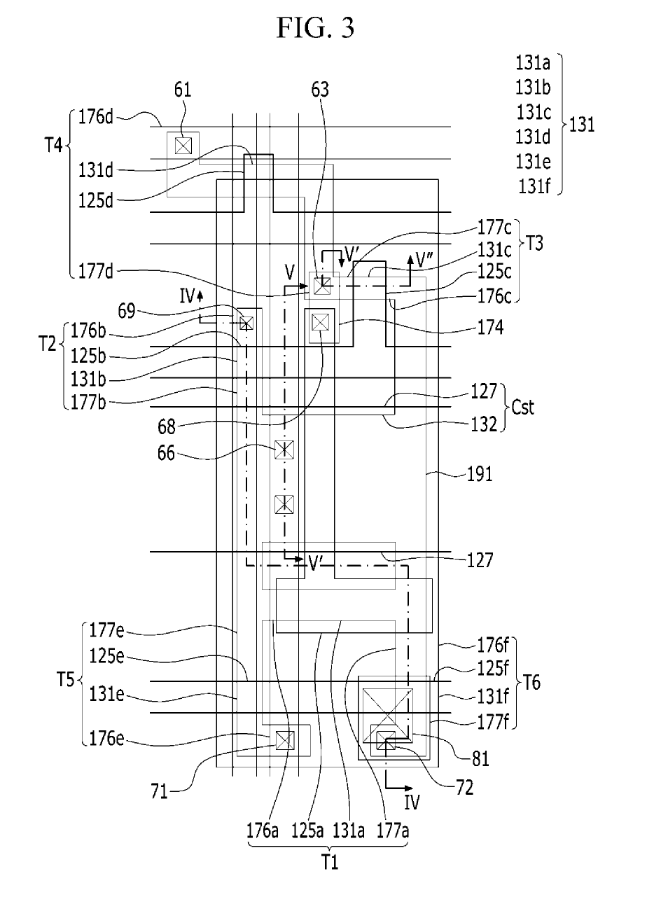

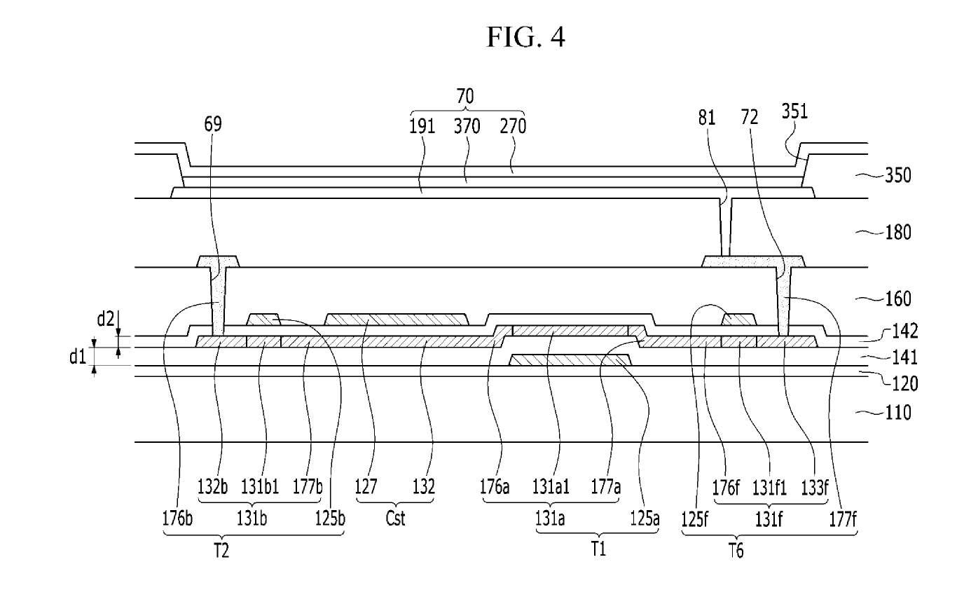

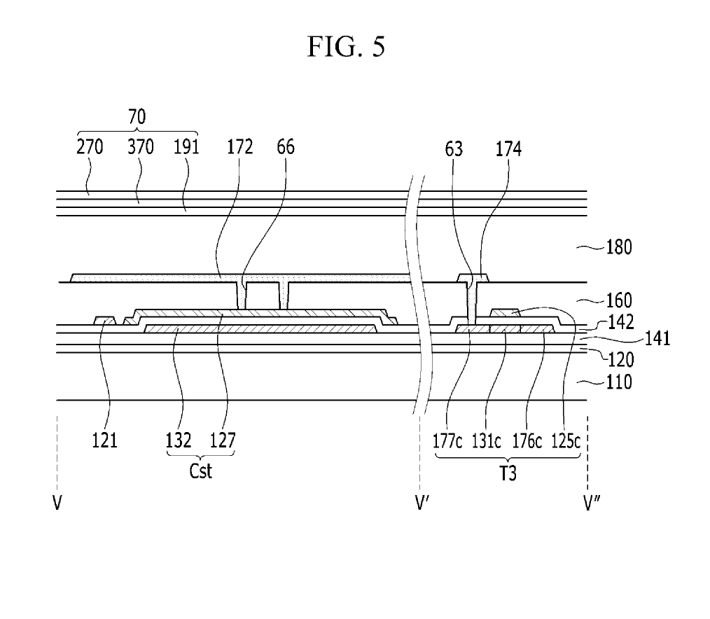

FIG. 2 is a view schematically illustrating a plurality of transistors and capacitors of the organic light emitting diode display according to exemplary embodiments of the present invention, FIG. 3 is a layout view of one pixel of FIG. 2, FIG. 4 is a cross-sectional view of the organic light emitting diode display of FIG. 3, which is taken along line IV-IV, and FIG. 5 is a cross-sectional view of the organic light emitting diode display of FIG. 3, which is taken along line V-V′ and line V′-V″.

As illustrated in FIG. 2, for example, the organic light emitting diode display may include the scan line 121, the prior scan line 122, the light emission control line 123, and the initialization voltage line 124 applying the scan signal Sn, the prior scan signal Sn-1, the light emission control signal En, and the initialization voltage Vint, respectively, and formed in a row direction, and the data line 171 and the driving voltage line 172 crossing the scan line 121, the prior scan line 122, the light emission control line 123, and the initialization voltage line 124 and applying the data signal Dm and the driving voltage ELVDD, respectively, to the pixel.

Further, for example, the driving transistor T1, the switching transistor T2, the compensation transistor T3, the initialization transistor T4, the operation control transistor T5, the light emission control transistor T6, the storage capacitor Cst, and the organic light emitting diode (OLED) are formed in the pixel.

In some examples, the driving transistor T1, the switching transistor T2, the compensation transistor T3, the initialization transistor T4, the operation control transistor T5, and the light emission control transistor T6 may be formed along a semiconductor layer 131, and the semiconductor layer 131 may be formed to be bent in various shapes. The semiconductor layer 131 may be formed of polysilicon or an oxide semiconductor. The oxide semiconductor may include at least one of oxides having titanium (Ti), hafnium (Hf), zirconium (Zr), aluminum (Al), tantalum (Ta), germanium (Ge), zinc (Zn), gallium (Ga), tin (Sn), and indium (In) as a base, and complex oxides thereof, such as at least one of zinc oxide (ZnO), indium-gallium-zinc oxide (InGaZnO4), indium-zinc oxide (Zn—In—O), zinc-tin oxide (Zn—Sn—O) indium-gallium oxide (In—Ga—O), indium-tin oxide (In—Sn—O), indium-zirconium oxide (In—Zr—O), indium-zirconium-zinc oxide (In—Zr—Zn—O), indium-zirconium-tin oxide (In—Zr—Sn—O), indium-zirconium-gallium oxide (In—Zr—Ga—O), indium-aluminum oxide (In—Al—O), indium-zinc-aluminum oxide (In—Zn—Al—O), indium-tin-aluminum oxide (In—Sn—Al—O), indium-aluminum-gallium oxide (In—Al—Ga—O), indium-tantalum oxide (In—Ta—O), indium-tantalum-zinc oxide (In—Ta—Zn—O), indium-tantalum-tin oxide (In—Ta—Sn—O), indium-tantalum-gallium oxide (In—Ta—Ga—O), indium-germanium oxide (In—Ge—O), indium-germanium-zinc oxide (In—Ge—Zn—O), indium-germanium-tin oxide (In—Ge—Sn—O), indium-germanium-gallium oxide (In—Ge—Ga—O), titanium-indium-zinc oxide (Ti—In—Zn—O), and hafnium-indium-zinc oxide (Hf—In—Zn—O). In the case where the semiconductor layer 131 is formed of the oxide semiconductor, a separate protective layer may be added to protect the oxide semiconductor that is weak with regard to an external environment such as high temperatures.

For example, the semiconductor layer 131 may include a channel region that is subjected to channel doping with an N-type impurity or a P-type impurity, and a source region and a drain region that are formed at respective sides of the channel region and formed by doping a doping impurity having a type that is opposite to that of the doping impurity doped in the channel region.

Hereinafter, a flat surface type of structure of the organic light emitting diode display according to exemplary embodiments of the present invention will be first described in detail with reference to FIG. 2 and FIG. 3, and a lamination structure thereof will be described in detail with reference to FIG. 4 and FIG. 5.

For example, as shown in FIG. 2 and FIG. 3, the pixel of the organic light emitting diode display may include the driving transistor T1, the switching transistor T2, the compensation transistor T3, the initialization transistor T4, the operation control transistor T5, the light emission control transistor T6, the storage capacitor Cst, and the organic light emitting diode (OLED). The transistors T1, T2, T3, T4, T5, and T6 may be formed along the semiconductor layer 131, and the semiconductor layer 131 may include a driving semiconductor layer 131a formed in the driving transistor T1, a switching semiconductor layer 131b formed in the switching transistor T2, a compensation semiconductor layer 131c formed in the compensation transistor T3, an initialization semiconductor layer 131d formed in the initialization transistor T4, an operation control semiconductor layer 131e formed in the operation control transistor T5, and a light emission control semiconductor layer 131f formed in the light emission control transistor T6.

The driving transistor T1 may include the driving semiconductor layer 131a, a driving gate electrode 125a, a driving source electrode 176a, and a driving drain electrode 177a. The driving source electrode 176a corresponds to a driving source region 176a doped with the impurity in the driving semiconductor layer 131a, and the driving drain electrode 177a corresponds to a driving drain region 177a doped with the impurity in the driving semiconductor layer 131a. The driving gate electrode 125a overlaps the driving semiconductor layer 131a.

For example, the switching transistor T2 may include the switching semiconductor layer 131b, a switching gate electrode 125b, a switching source electrode 176b, and a switching drain electrode 177b. The switching source electrode 176b is a portion protruding from the data line 171, and the switching drain electrode 177b corresponds to a switching drain region 177b doped with an impurity in the switching semiconductor layer 131b.

The switching gate electrode 125b may be formed with the same layer and the same material as the scan line 121, the prior scan line 122, the light emission control line 123, a compensation gate electrode 125c, an initialization gate electrode 125d, and a second storage capacitive plate 127, and may be formed with a different layer from the driving gate electrode 125a.

The compensation transistor T3 may include the compensation semiconductor layer 131c, the compensation gate electrode 125c, a compensation source electrode 176c, and a compensation drain electrode 177c, the compensation source electrode 176c corresponds to a compensation source region 176c doped with the impurity in the compensation semiconductor layer 131c, and the compensation drain electrode 177c corresponds to a compensation drain region 177c doped with the impurity in the compensation semiconductor layer 131c and is connected to one end of a connection member 174.

For example, the initialization transistor T4 may include the initialization semiconductor layer 131d, the initialization gate electrode 125d, an initialization source electrode 176d, and an initialization drain electrode 177d. The initialization source electrode 176d as a portion of the initialization voltage line 124 is connected to the initialization semiconductor layer 131d through a contact hole 61 formed in a second gate insulating layer 142, an interlayer insulating layer 160, and a protective layer 180, and the initialization drain electrode 177d as one end of the connection member 174 is connected to the initialization semiconductor layer 131d through a contact hole 63 formed in the second gate insulating layer 142 and the interlayer insulating layer 160.

The operation control transistor T5 may include the operation control semiconductor layer 131e, an operation control gate electrode 125e, an operation control source electrode 176e, and an operation control drain electrode 177e. The operation control source electrode 176e as a portion of the driving voltage line 172 is connected to the operation control semiconductor layer 131e through a contact hole 71, and the operation control drain electrode 177e corresponds to an operation control drain region 177e doped with the impurity in the operation control semiconductor layer 131e.

The light emission control transistor T6 may include the light emission control semiconductor layer 131f, a light emission control gate electrode 125f, a light emission control source electrode 176f, and a light emission control drain electrode 177f. The light emission control source electrode 176f corresponds to a light emission control source region 176f doped with the impurity in the light emission control semiconductor layer 131f.

For example, an end of the driving semiconductor layer 131a of the driving transistor T1 is connected to the switching semiconductor layer 131b and the operation control semiconductor layer 131e, and the other end of the driving semiconductor layer 131a is connected to the compensation semiconductor layer 131c and the light emission control semiconductor layer 131f. Therefore, the driving source electrode 176a is connected to the switching drain electrode 177b and the operation control drain electrode 177e, and the driving drain electrode 177a is connected to the compensation source electrode 176c and the light emission control source electrode 176f.

The storage capacitor Cst may include a first storage capacitive plate 132 and the second storage capacitive plate 127 with the second gate insulating layer 142 interposed therebetween. Herein, the second gate insulating layer 142 is a dielectric material, and a storage capacitance is determined by charges accumulated in the storage capacitor Cst and a voltage between both capacitive plates 132 and 127.

The first storage capacitive plate 132 may be formed with the same material and the same layer as the semiconductor layer 131, and the second storage capacitive plate 127 may be formed with the same material and the same layer as the scan line 121, the prior scan line 122, the light emission control line 123, the driving gate electrode 125a, the switching gate electrode 125b, the compensation gate electrode 125c, the operation control gate electrode 125e, and the light emission control gate electrode 125f. The second storage capacitor plate 127 may be formed of the gate wire including at least one metal of aluminum (Al), chromium (Cr), molybdenum (Mo), titanium (Ti), tantalum (Ta), an Al—Ni—La alloy, and an Al—Nd alloy.

Also, a portion of the driving voltage line 172 passing through the storage capacitor Cst corresponds to the operation control source electrode 176e and is connected to the operation control semiconductor layer 131e through the contact hole 71 and another portion of the driving voltage line 172 is connected to the second storage capacitive plate 127 through a contact hole 66 formed in the interlayer insulating layer 160.

The connection member 174 may be formed in parallel with the driving voltage line 172 on the same layer. The connection member 174 respectively connects the driving gate electrode 125a and the compensation semiconductor layer 131c through a contact hole 68 and the contact hole 63. Accordingly, the storage capacitor Cst stores a storage capacitance corresponding to a difference between the driving voltage ELVDD transferred through the driving voltage line 172 and the gate voltage of the driving gate electrode 125a.

Meanwhile, the switching transistor T2 is used as a switching element for selecting a pixel that is to emit light. The switching gate electrode 125b is connected to the scan line 121, the switching source electrode 176b is connected to the data line 171, and the switching drain electrode 177b is connected to the driving transistor T1 and the operation control transistor T5. In addition, the light emission control drain electrode 177f of the light emission control transistor T6 is directly connected through a contact hole 81 formed in the protective layer 180 to a pixel electrode 191 of an organic light emitting diode 70.

Hereinafter, referring to FIG. 4 and FIG. 5, a structure of the organic light emitting diode display according to exemplary embodiments of the present invention will be described in detail according to the lamination order.

In this case, the structure of the transistor will be described based on the driving transistor T1, the switching transistor T2, and the light emission control transistor T6. The compensation transistor T3 and the initialization transistor T4 are the same as most of the deposition structure of the switching transistor T2, and the operation control transistor T5 is the same as most of the deposition structure of the light emission control transistor T6, such that they are not described in further detail.

For example, a buffer layer 120 is formed on a substrate 110, and the substrate 110 is formed of an insulating substrate made of glass, quartz, ceramics, or plastics.

The driving gate electrode 125a is formed on the buffer layer 120, and a first gate insulating layer 141 made of silicon nitride (SiNx) or silicon dioxide (SiO2) is formed on the driving gate electrode 125a.

The driving semiconductor layer 131a, the switching semiconductor layer 131b, and the light emission control semiconductor layer 131f are formed on the first gate insulating layer 141. The driving semiconductor layer 131a may include a driving channel region 131a1 and the driving source region 176a and driving drain region 177a facing each other with the driving channel region 131a1 interposed therebetween, the switching semiconductor layer 131b may include a switching channel region 131b1 and the switching source region 132b and switching drain region 177b facing each other with the switching channel region 131b1 interposed therebetween, and the light emission control transistor T6 may include a light emission control channel region 131f1, the light emission control source region 176f, and a light emission control drain region 133f.

The second gate insulating layer 142 made of silicon nitride (SiNx) or silicon dioxide (SiO2) is formed on the driving semiconductor layer 131a, the switching semiconductor layer 131b, and the light emission control semiconductor layer 131f.

On the second gate insulating layer 142, gate wires 121, 123, 125b, 125c, 125e, 125f, and 127 including the scan line 121 including the switching gate electrode 125b and the compensation gate electrode 125c, the light emission control line 123 including the operation control gate electrode 125e and the light emission control gate electrode 125f, and the second storage capacitive plate 127 are formed.

As described above, differently from the other transistors T2, T3, T4, T5, T6, the driving transistor T1 has a bottom gate structure in which the driving gate electrode 125a is positioned under the driving semiconductor layer 131a. The thickness d1 of the first gate insulating layer 141 is thicker than the thickness d2 of the second gate insulating layer 142. Accordingly, the interval between the driving semiconductor layer 131a and the driving gate electrode 125a is widened. Therefore, a driving range of the gate voltage applied to the driving gate electrode 125a to express all grayscale values is widened.

The interlayer insulating layer 160 is formed on the gate wires 121, 123, 125b, 125c, 125e, 125f, and 127, and the second gate insulating layer 142. Like the first gate insulating layer 141 and the second gate insulating layer 142, the interlayer insulating layer 160 is made of a ceramic-based material such as silicon nitride (SiNx) or silicon dioxide (SiO2).

On the interlayer insulating layer 160, data wires including the data line 171 including the switching source electrode 176b, the connection member 174 including the initialization drain electrode 177d, and the driving voltage line 172 including the light emission control drain electrode 177f and the driving control source electrode 176e is formed. The switching source electrode 176b is connected to the switching source region 132b through a contact hole 69 formed in the second gate insulating layer 142 and the interlayer insulating layer 160.

Also, the light emission control drain electrode 177f is connected to the light emission control drain region 133f of the light emission control semiconductor layer 131f through a contact hole 72 formed in the second gate insulating layer 142 and the interlayer insulating layer 160.

The protective layer 180 is formed on the interlayer insulating layer 160 covering the data wires 171, 172, 174, and 177f, and the pixel electrode 191 and the initialization voltage line 124 are formed on the protective layer 180. The pixel electrode 191 is connected to the light emission control drain electrode 177f through the contact hole 81 formed in the protective layer 180, and the initialization voltage line 124 is connected to the initialization semiconductor layer 131d through the contact hole 61.

A barrier rib 350 is formed on an edge of the pixel electrode 191 and the protective layer 180, and the barrier rib 350 has a barrier rib opening 351 through which the pixel electrode 191 is exposed. The barrier rib 350 may be made of a resin such as a polyacrylate, polyimide resin, or silica-based inorganic materials.

An organic emission layer 370 is formed on the pixel electrode 191 exposed through the barrier rib opening 351, and a common electrode 270 is formed on the organic emission layer 370. As described above, the organic light emitting diode 70 including the pixel electrode 191, the organic emission layer 370, and the common electrode 270 is formed.

Herein, the pixel electrode 191 is an anode that is a hole injection electrode, and the common electrode 270 is a cathode that is an electron injection electrode. However, exemplary embodiments of the present invention are not limited thereto. For example, the pixel electrode 191 may be the cathode and the common electrode 270 may be the anode according to the driving method of the organic light emitting diode display. Holes and electrons are injected from the pixel electrode 191 and the common electrode 270 into the organic emission layer 370, and when excitons that are the injected holes and electrons bonded to each other fall from an exited state to a ground state, light is emitted.

For example, the organic emission layer 370 may be formed of a low molecular weight organic material or a high molecular weight organic material such as PEDOT (poly(3,4-ethylenedioxythiophene)). Further, the organic emission layer 370 may be formed of a multilayer including an emission layer and one or more of a hole injection layer HIL, a hole transport layer HTL, an electron transport layer ETL, and an electron injection layer EIL. In the case where all the layers are included, the hole injection layer HIL is disposed on the pixel electrode 191 that is the anode, and the hole transport layer HTL, the emission layer, the electron transport layer ETL, and the electron injection layer EIL are sequentially laminated thereon.

The organic emission layer 370 may include a red organic emission layer emitting light having a red color, a green organic emission layer emitting light having a green color, and a blue organic emission layer emitting light having a blue color, and the red organic emission layer, the green organic emission layer, and the blue organic emission layer are respectively formed in a red pixel, a green pixel, and a blue pixel to implement a color image.

Further, the organic emission layer 370 may implement the color image by laminating all of the red organic emission layer, the green organic emission layer, and the blue organic emission layer in the red pixel, the green pixel, and the blue pixel together, and forming a red color filter, a green color filter, and a blue color filter for each pixel. In some examples, a white organic emission layer emitting light having a white color may be formed in all of the red pixel, the green pixel, and the blue pixel, and the red color filter, the green color filter, and the blue color filter may be formed for each pixel to implement the color image. In the case where the color image is implemented by using the white organic emission layer and the color filter, deposition masks for depositing the red organic emission layer, the green organic emission layer, and the blue organic emission layer on each pixel, that is, the red pixel, the green pixel, and the blue pixel, may not be used.

Needless to say, the white organic emission layer described in exemplary embodiments may be formed of one organic emission layer, and may include even a constitution in which a plurality of organic emission layers are laminated to emit light having the white color.

For example, a constitution in which at least one yellow organic emission layer and at least one blue organic emission layer are combined to emit light having the white color, a constitution in which at least one cyan organic emission layer and at least one red organic emission layer are combined to emit light having the white color, a constitution in which at least one magenta organic emission layer and at least one green organic emission layer are combined to emit light having the white color, or the like may be included.

For example, a sealing member (not illustrated) for protecting the organic light emitting diode 70 may be formed on the common electrode 270, may be sealed by a sealant on the substrate 110, and may be formed of various materials such as glass, quartz, ceramic, plastics, or metal. Meanwhile, a sealing thin film layer may be formed by depositing an inorganic layer and an organic layer on the common electrode 270 while not using the sealant.

On one exemplary embodiment, the switching transistor and the compensation transistor are formed of the top gate structure, however the switching transistor and the compensation transistor may be formed of a bottom gate structure as in the other exemplary embodiment.

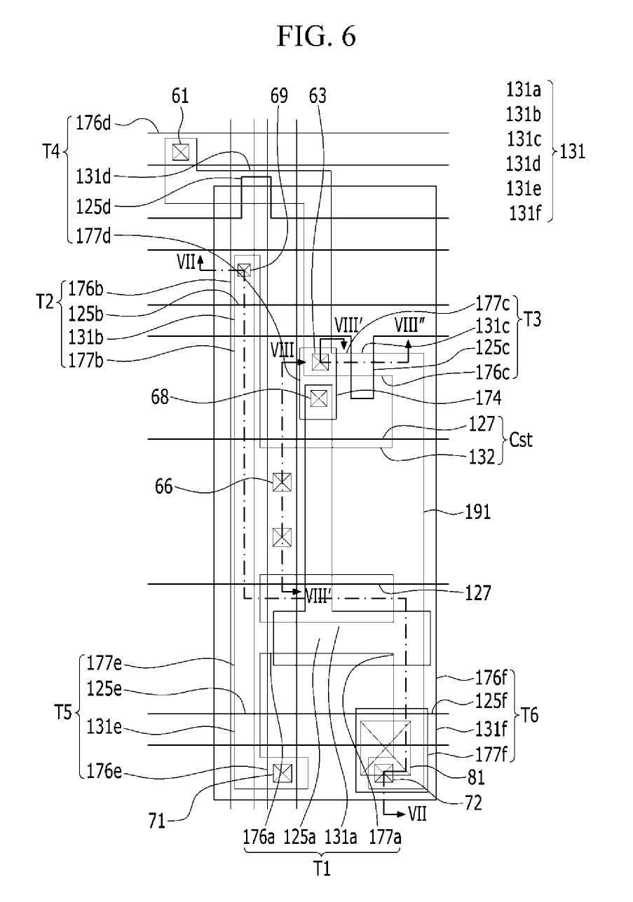

Next, referring to FIG. 6 to FIG. 8, the organic light emitting diode (OLED) display according to exemplary embodiments of the present invention will be described.

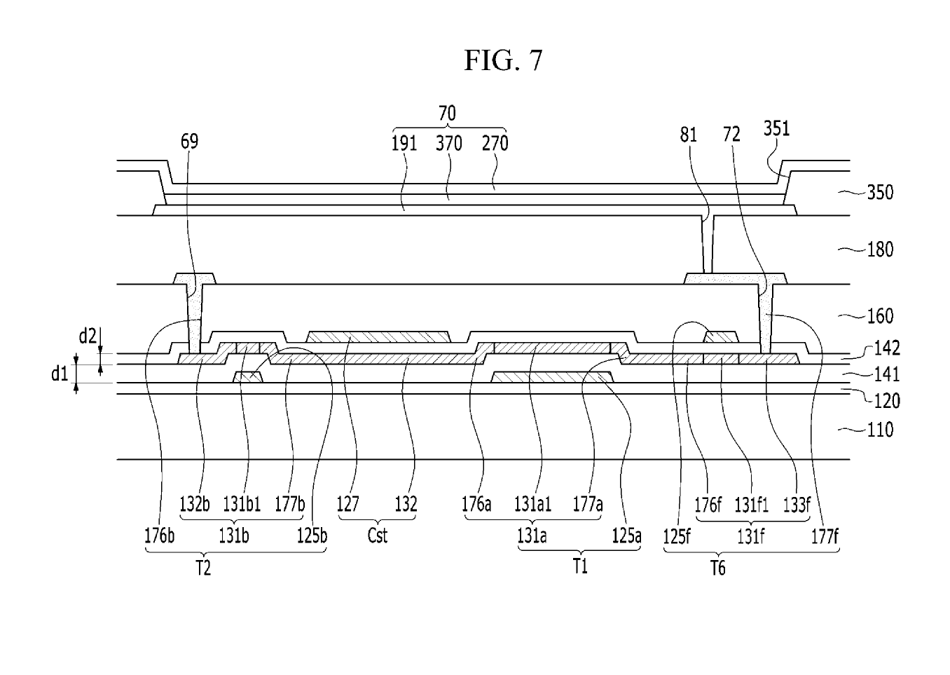

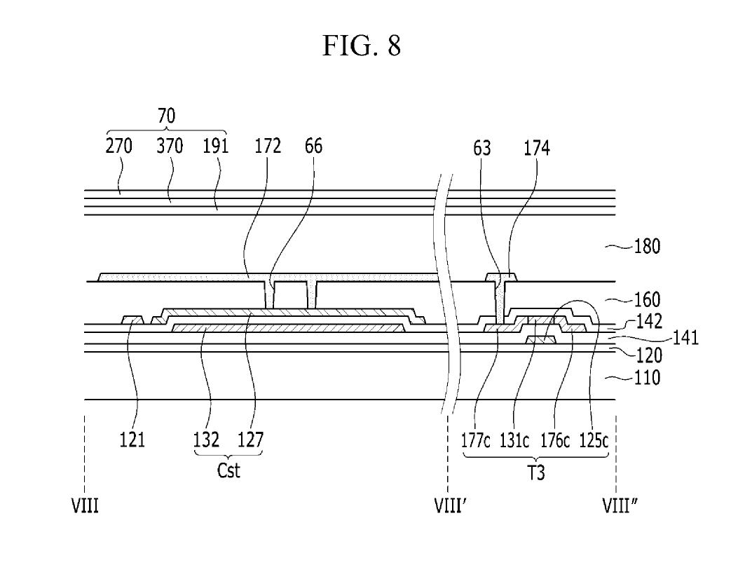

FIG. 6 is a layout view of one pixel of an organic light emitting diode display according to exemplary embodiments of the present invention, FIG. 7 is a cross-sectional view of the organic light emitting diode display of FIG. 6 taken along line VII-VII, and FIG. 8 is a cross-sectional view of the organic light emitting diode display of FIG. 6 taken along line VIII-VIII′ and VIII′-VIII″.

The following exemplary embodiment is substantially equivalent to the first exemplary embodiment shown in FIG. 1 to FIG. 5 except for the switching transistor and the compensation transistor such that the overlapping description is omitted.

As shown in FIG. 6 to FIG. 8, the scan line 121 including the driving gate electrode 125a, the switching gate electrode 125b, and the compensation gate electrode 125c is formed on the buffer layer 120 of the organic light emitting diode (OLED) display according to exemplary embodiments of the present invention. The first gate insulating layer 141 is formed on the driving gate electrode 125a, the switching gate electrode 125b, and the compensation gate electrode 125c. Also, the driving semiconductor layer 131a, the switching semiconductor layer 131b, the compensation semiconductor layer 131c, and the light emission control semiconductor layer 131f are formed on the first gate insulating layer 141. The second gate insulating layer 142 is formed on the driving semiconductor layer 131a, the switching semiconductor layer 131b, the compensation semiconductor layer 131c, and the light emission control semiconductor layer 131f, and gate wires 123, 125e, 125f, 127 including the operation control gate electrode 125e, the light emission control line 123 including the light emission control gate electrode 125f, and the second storage capacitive plate 127 are formed on the second gate insulating layer 142.

As described above, differently from the other transistors T4, T5, and T6, the driving transistor T1, the switching transistor T2, and the compensation transistor T3 are formed of the bottom gate structure in which the driving gate electrode 125a, the switching gate electrode 125b, and the compensation gate electrode 125c are positioned under the driving semiconductor layer 131a, the switching semiconductor layer 131b, and the compensation semiconductor layer 131c. At this time, the thickness d1 of the first gate insulating layer 141 is greater than the thickness d2 of the second gate insulating layer 142. Accordingly, the interval between the driving semiconductor layer 131a and the driving gate electrode 125a and the interval between the compensation semiconductor layer 131c and the compensation gate electrode 125c is increased. Accordingly, the current change for the voltage may be insensitive such that a wide driving range may be obtained, thereby easily expressing all grayscales.

On the other hand, in the one exemplary embodiment, the first storage capacitive plate of the storage capacitor is formed of the semiconductor layer, however the first storage capacitive plate may be formed of the gate wire as another exemplary embodiment.

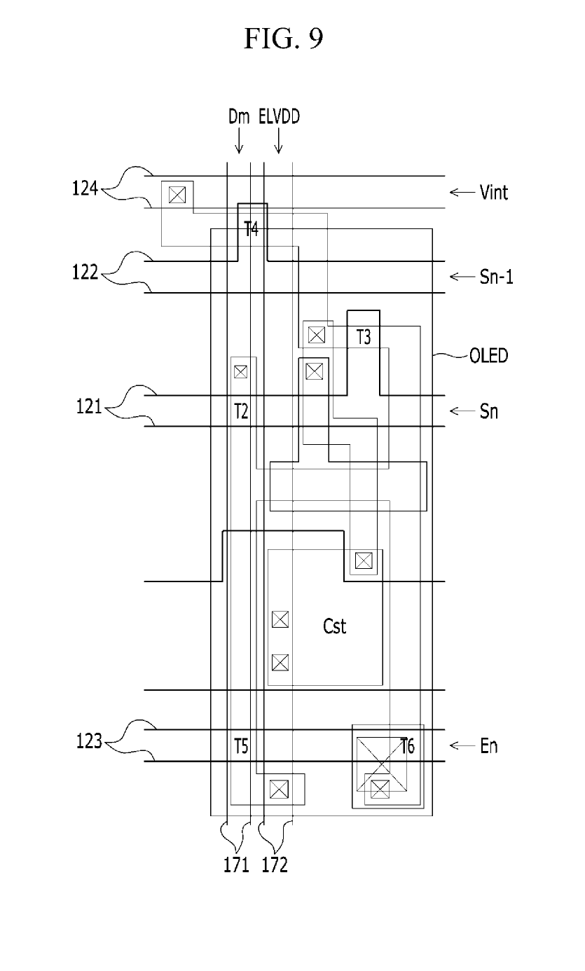

Next, referring to FIG. 9 to FIG. 12, an organic light emitting diode (OLED) display according to exemplary embodiments of the present invention will be described.

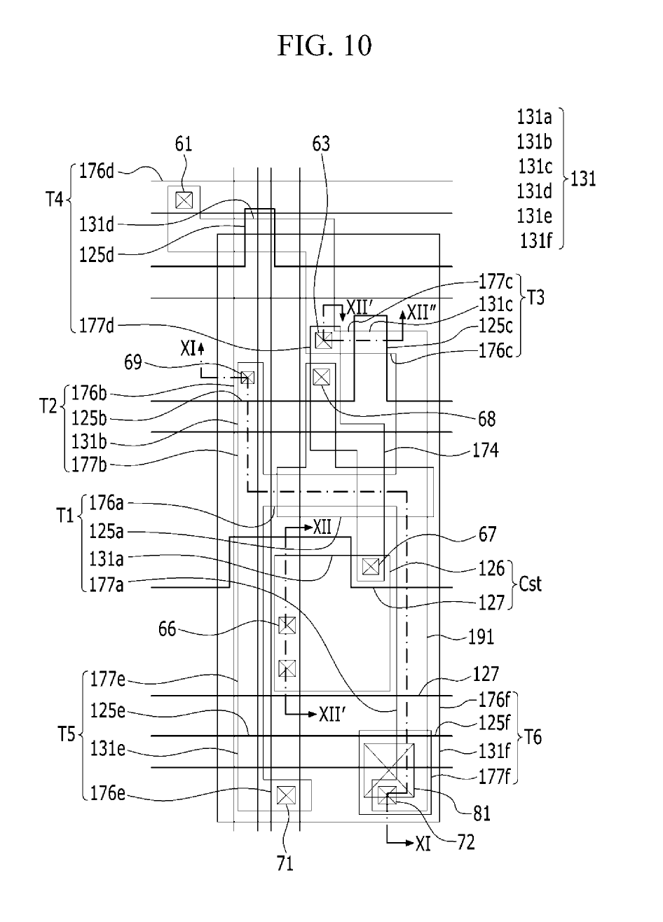

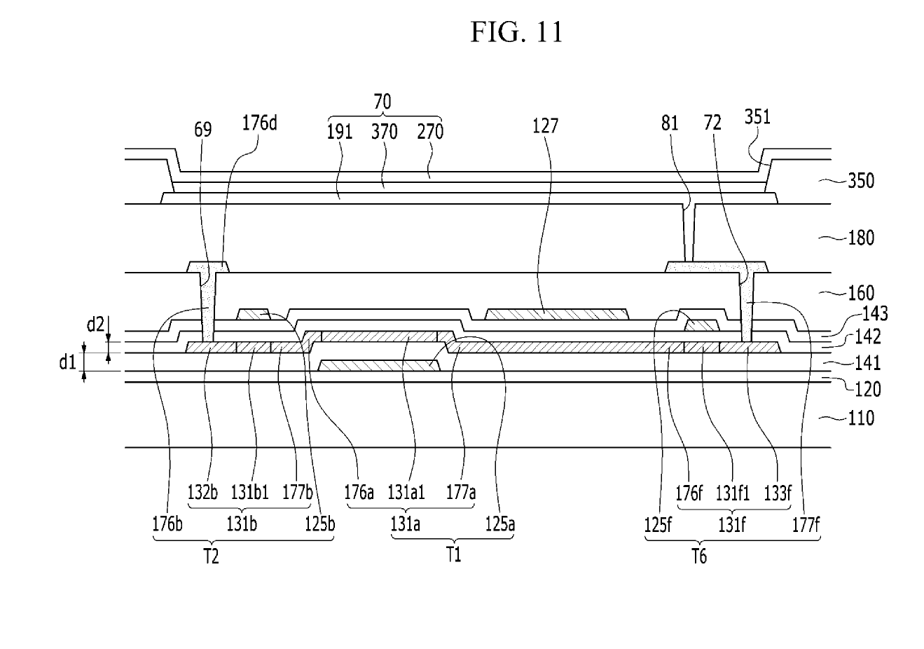

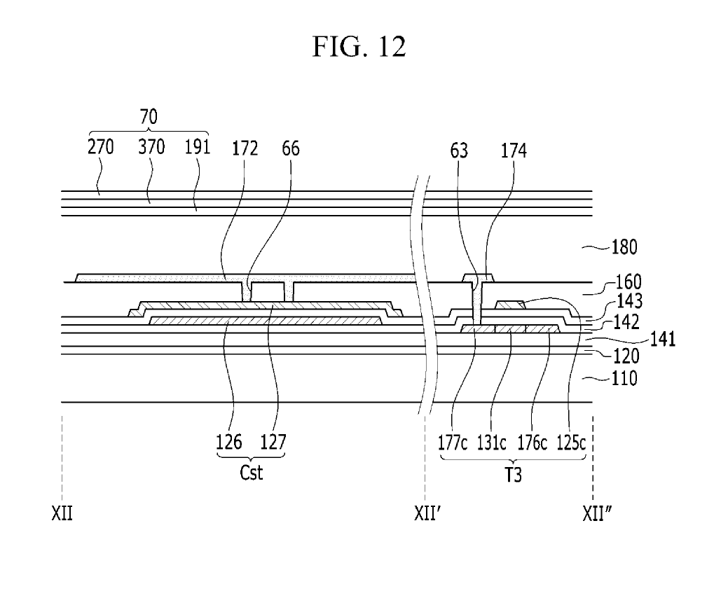

FIG. 9 is a view schematically illustrating a plurality of transistors and capacitors of the organic light emitting diode display according to exemplary embodiments of the present invention, FIG. 10 is a specific layout view of one pixel of FIG. 9, FIG. 11 is a cross-sectional view of the organic light emitting diode (OLED) display of FIG. 10 taken along the line XI-XI, and FIG. 12 is a cross-sectional view of the organic light emitting diode (OLED) display of FIG. 10 taken along the lines XII-XII′ and XII′-XII″.

The following exemplary embodiment is substantially equivalent to the first exemplary embodiment shown in FIG. 1 to FIG. 5 except for a position of the first storage capacitive plate and the scan line.

As shown in FIG. 9 to FIG. 12, according to exemplary embodiments of the present invention, the first gate wires 123, 125e, 125f, and 126 including the light emission control line 123 including the operation control gate electrode 125e and the light emission control gate electrode 125f and the first storage capacitive plate 126 are formed on the second gate insulating layer 142 of the organic light emitting diode (OLED) display.

A third gate insulating layer 143 is formed on the first gate wires 123, 125e, 125f, and 126 and the second gate insulating layer 142. The third gate insulating layer 143 is formed of silicon nitride (SiNx) or silicon dioxide (SiO2).

The second gate wires 121, 125b, 125c, 127 including the scan line 121 including the switching gate electrode 125b and the compensation gate electrode 125c and the second storage capacitive plate 127 are formed on the third gate insulating layer 143.

At this time, the first storage capacitive plate 126 may include at least one metal of aluminum (Al), chromium (Cr), molybdenum (Mo), titanium (Ti), tantalum (Ta), an Al—Ni—La alloy, and an Al—Nd alloy such that the storage capacitance may be improved compared with the structure in which the first storage capacitive plate 126 is formed of the semiconductor layer.

Meanwhile, in this exemplary embodiment, the driving transistor does not include the storage capacitor, however the driving transistor may overlap a storage capacitor.

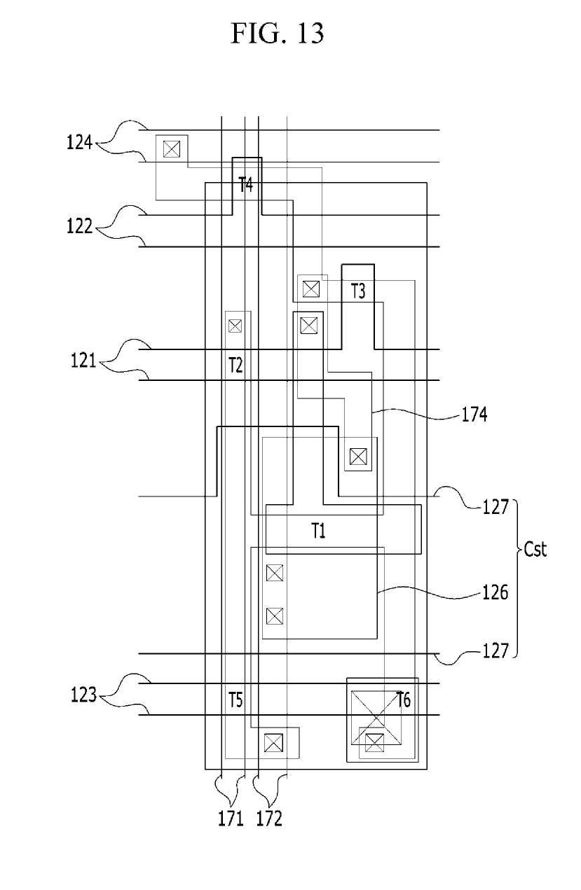

Next, an organic light emitting diode (OLED) display according to exemplary embodiments of the present invention will be described with reference to FIG. 13.

FIG. 13 is a detailed layout view of one pixel of an organic light emitting diode (OLED) display according to exemplary embodiments of the present invention.

The following exemplary embodiment is substantially equivalent to the third exemplary embodiment shown in FIG. 9 to FIG. 12 except for the driving transistor and the storage capacitor overlapping each other.

As shown in FIG. 13, the storage capacitor of the organic light emitting diode (OLED) display overlaps the driving transistor. Accordingly, by overlapping the first storage capacitive plate 126 and the second storage capacitive plate 127 with the gate wire, the storage capacitance may be improved and simultaneously a pixel inner space may be minimized such that the pixel size may be minimized, thereby being applied to high resolution.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. An organic light emitting diode (OLED) display comprising:
a substrate;
a driving gate electrode disposed on the substrate;
a first gate insulating layer covering the substrate and the driving gate electrode;
a semiconductor layer disposed on the first gate insulating layer and comprising a switching semiconductor layer and a driving semiconductor layer spaced apart from each other;
a second gate insulating layer covering the semiconductor layer;
a switching gate electrode formed on the second gate insulating layer and overlapping the switching semiconductor layer; and
an interlayer insulating layer covering the switching gate electrode and the second gate insulating layer,
wherein a thickness of the first gate insulating layer is greater than a thickness of the second gate insulating layer.

2. The organic light emitting diode (OLED) display of claim 1, further comprising:
a scan line disposed on the substrate and configured to transmit a scan signal;
a data line and a driving voltage line intersecting the scan line and configured to respectively transmit a data signal and a driving voltage;
a switching transistor connected to the scan line and the data line and comprising the switching semiconductor layer and the switching gate electrode;
a driving transistor connected to a switching drain electrode of the switching transistor and comprising the driving semiconductor layer and the driving gate electrode;
a compensation transistor configured to compensate a threshold voltage of the driving transistor in response to the scan signal, the compensation transistor connected to the driving transistor; and
an organic light emitting diode (OLED) connected to a driving drain electrode of the driving transistor.

3. The organic light emitting diode (OLED) display of claim 2, wherein
the scan line is formed with the same layer as the switching gate electrode.

4. The organic light emitting diode (OLED) display of claim 2, wherein
the scan line is formed with the same layer as the driving gate electrode.

5. The organic light emitting diode (OLED) display of claim 4, wherein
the compensation gate electrode of the compensation transistor is formed with the same layer as the driving gate electrode.

6. The organic light emitting diode (OLED) display of claim 5, further comprising:
a first storage capacitive plate disposed on the first gate insulating layer; and
a storage capacitor comprising a second storage capacitive plate and formed on the second gate insulating layer covering the first storage capacitive plate and overlapping the first storage capacitive plate.

7. The organic light emitting diode (OLED) display of claim 6, further comprising:
a third gate insulating layer disposed between the second gate insulating layer and the interlayer insulating layer,
wherein the second gate insulating layer and the third gate insulating layer are disposed between the switching semiconductor layer and the switching gate electrode of the switching transistor.

8. The organic light emitting diode (OLED) display of claim 7, wherein
the second gate insulating layer and the third gate insulating layer are disposed between the compensation semiconductor layer and the compensation gate electrode of the compensation transistor.

9. The organic light emitting diode (OLED) display of claim 8, further comprising:
a first storage capacitive plate formed on the second gate insulating layer; and a storage capacitor comprising the second storage capacitive plate and formed on the third gate insulating layer covering the first storage capacitive plate and overlapping the first storage capacitive plate.

10. The organic light emitting diode (OLED) display of claim 9, wherein
the storage capacitor overlaps the driving transistor.

11. A display comprising:
a driving gate electrode disposed on a substrate;
a first gate insulating layer disposed on the driving gate electrode;
a driving semiconductor layer, a switching semiconductor layer, and a light emission control semiconductor layer disposed on the first gate insulating layer, the driving gate electrode formed under the driving semiconductor layer, wherein
a thickness of the first gate insulating layer is greater than a thickness of the second gate insulating layer, and wherein
an interval between the driving semiconductor layer and the driving gate electrode is widened.

12. A method comprising:
forming a driving gate on a substrate;
forming a first gate insulator covering the substrate and the driving gate electrode;
forming a semiconductor layer on the first gate insulating layer, the semiconductor layer comprising a switching semiconductor layer and a driving semiconductor layer spaced apart from each other, and a second gate insulating layer covering the semiconductor layer;
forming a switching gate electrode on the second gate insulating layer, the switching gate electrode overlapping the switching semiconductor layer; and
forming an interlayer insulating layer covering the switching gate electrode and the second gate insulating layer, wherein the first gate insulating layer is formed thicker than the second gate insulating layer.
